(19) United States
(12) Patent Application Publication
(10) Pub. No.: US 2024/0364286 A1
(43) Pub. Date: Oct. 31, 2024

(54) Amplifying circuit having supplemental transconductance and stable common-mode feedback

(71) Applicant: REALTEK SEMICONDUCTOR CORPORATION, HSINCHU (TW)

(72) Inventor: CHUNG-YU LIN, HSINCHU (TW)

(21) Appl. No.: 18/601,477

(22) Filed: Mar. 11, 2024

(30) Foreign Application Priority Data
Apr. 26, 2023 (TW) 112115602

(51) Int. Cl. H03F 3/45

(52) U.S. Cl. CPC H03F 3/45215; H03F 3/45475; H03F 2203/45288

(57) ABSTRACT

An amplifying circuit allows its loading circuit to contribute a transconductance to increase the bandwidth of the amplifying circuit, and thereby achieves common-mode stabilization. The amplifying circuit includes a first and a second amplifying circuit. The first amplifying circuit is coupled between a high-voltage terminal and a low-voltage terminal, and outputs a first amplified signal according to an input signal. The second amplifying circuit includes: an input-stage circuit configured to receive the input signal and output an input-stage output signal to intermediate nodes; a transconductance and loading circuit coupled between the high-voltage terminal and the input-stage circuit, and configured to output a transconductance-enhancement signal to the intermediate nodes according to the first amplified signal; and an output-stage circuit coupled between the high-voltage terminal and the low-voltage terminal and coupled to the intermediate nodes, and configured to output an output signal according to the input-stage output signal and the transconductance-enhancement signal.

### BACKGROUND OF THE INVENTION

### 1. Field of the Invention

The present disclosure relates to an amplifying circuit, especially to an amplifying circuit characterized by a supplemental transconductance and a stable common-mode feedback.

### 2. Description of Related Art

A general multistage amplifier (e.g., a two-stage operational amplifier found in: Behzad Razvai, “Design of Analog CMOS Integrated Circuit”, Chap. 9, FIG. 9.65) includes an input-stage circuit, a loading circuit, and an output-stage circuit. The input-stage circuit and the output-stage circuit jointly determine the transconductance of the multistage amplifier while the loading circuit has no influence on the transconductance of the multistage amplifier. The input-stage circuit not only contributes to the transconductance of the multistage amplifier but also functions as a loading; meanwhile, the loading circuit only functions as a loading. In light of the above, the potential of the loading circuit to contribute to the transconductance of the multistage amplifier is not developed.

### SUMMARY OF THE INVENTION

An object of the present disclosure is to provide an amplifying circuit without the inadequacy of the prior art.

An embodiment of the amplifying circuit of the present disclosure includes a first amplifying circuit and a second amplifying circuit. The first amplifying circuit is coupled between a high-voltage terminal and a low-voltage terminal, and is configured to output a first amplified signal according to an input signal and achieve the common-mode stabilization. The second amplifying circuit includes an input-stage circuit, a transconductance and loading circuit, and an output-stage circuit. The input-stage circuit is configured to receive the input signal and accordingly output an input-stage output signal to a set of intermediate node(s). The transconductance and loading circuit is coupled between the high-voltage terminal and the input-stage circuit, and is configured to output a transconductance-enhancement signal to the set of intermediate node(s) according to the first amplified signal. The output-stage circuit is coupled between the high-voltage terminal and the low-voltage terminal and further coupled to the set of intermediate node(s), and is configured to output an output signal according to the input-stage output signal and the transconductance-enhancement signal. This embodiment is characterized in that: not only the input-stage circuit and the output-stage circuit but also the transconductance and loading circuit contributes to the transconductance of the second amplifying circuit, which increases the bandwidth of the whole amplifying circuit.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of the amplifying circuit of the present disclosure.

FIG. 2 shows an embodiment of the first amplifying circuit of FIG. 1.

FIG. 3 shows an embodiment of a feedback-voltage generating circuit for generating the feedback voltage of FIG. 2.

FIG. 4 shows another embodiment of the first amplifying circuit of FIG. 1.

FIG. 5 shows another embodiment of the amplifying circuit of the present disclosure.

FIG. 6 shows the relation between the gain and the frequency with respect to the prior art, the amplifying circuit of FIG. 2, and the amplifying circuit of FIG. 4.

### DETAILED DESCRIPTION OF THE PREFERRED EMBODIMENTS

The present specification discloses an amplifying circuit including a loading circuit capable of contributing to the transconductance of the amplifying circuit. Accordingly, the bandwidth of the amplifying circuit is increased, and the efficacy of common-mode stabilization including the efficacy of direct-current (DC) stabilization is improved.

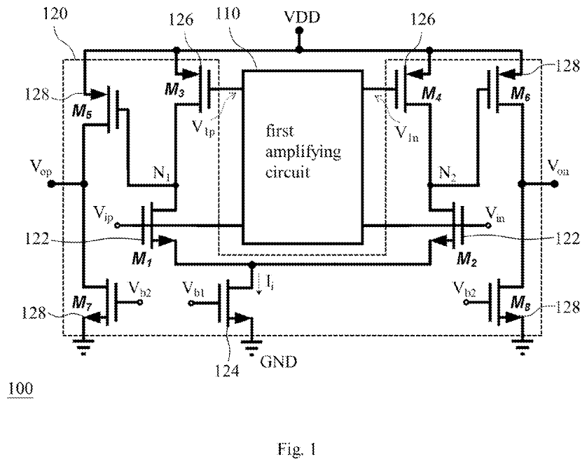

FIG. 1 shows an embodiment of the amplifying circuit of the present disclosure. The amplifying circuit 100 of FIG. 1 includes a first amplifying circuit 110 and a second amplifying circuit 120.

Referring to FIG. 1, the first amplifying circuit 110 is coupled between a high-voltage terminal VDD (e.g., a power supply terminal) and a low-voltage terminal GND (e.g., a ground terminal). The first amplifying circuit 110 is configured to output a first amplified signal (e.g., a differential signal composed of complementary signals V₁ₚ, V₁ₙ) varying based on a DC voltage to the second amplifying circuit 120 in accordance with an input signal (e.g., a differential signal composed of complementary signals V₁ₚ, V₁ₙ).

Referring to FIG. 1, the second amplifying circuit 120 includes an input-stage circuit 122, a bias circuit 124, a transconductance and loading circuit 126, and an output-stage circuit 128. A nonrestrictive embodiment of the input-stage circuit 122 is a pair of NMOS transistors M₁, M₂; and this pair of NMOS transistors M₁, M₂ is configured to receive the input signal V₁ₚ, Vᵢₙ and accordingly output an input-stage output signal (i.e., signals at the drain terminals of the pair of NMOS transistors M₁, M₂) to a set of intermediate node(s) N₁, N₂. The input-stage circuit 122 can be realized with a pair of PMOS transistors (i.e., a pair of p-channel MOSFETs) according to implementation needs in an alternative embodiment.

Referring to FIG. 1, a nonrestrictive embodiment of the bias circuit 124 is an NMOS transistor (i.e., an n-channel MOSFET) configured to regulate the current Iᵢ passing through the input-stage circuit 122 in accordance with a predetermined bias V_{b1}, wherein the predetermined bias V_{b1} is determined according to implementation needs.

Referring to FIG. 1, a nonrestrictive embodiment of the transconductance and loading circuit 126 is a pair of PMOS transistors M₃, M₄ coupled between the high-voltage terminal VDD and the input-stage circuit 122, wherein the pair of PMOS transistors is configured to output a transconductance-enhancement signal (not shown in FIG. 1) to the set of intermediate node(s) N₁, N₂ according to the first amplified signal V₁ₚ, V₁ₙ.

Referring to FIG. 1, a nonrestrictive embodiment of the output-stage circuit 128 includes a pair of PMOS transistors Ms, M₆ and a pair of NMOS transistors M₇, M₈, and is coupled between the high-voltage terminal VDD and the low-voltage terminal GND and further coupled to the set of intermediate node(s) N₁, N₂. The pair of PMOS transistors Ms, M₆ is configured to output an output signal Vₒₚ, Vₒₙ according to the input-stage output signal outputted by the input-stage circuit 122 and the transconductance-enhancement signal outputted by the transconductance and loading circuit 126. The pair of NMOS transistors M₇, Ma is configured to regulate the current passing through the output-stage circuit 128 in accordance with a predetermined bias V_{b2} which is determined according to implementation needs.

It is noted that the second amplifying circuit 120 of FIG. 1 is a two-stage operational amplifier, wherein the input-stage circuit 122, the transconductance and loading circuit 126, and the output-stage circuit 128 jointly contribute to the transconductance of the second amplifying circuit 120. This feature can be appreciated from the equation (2) and equation (4) mentioned in the later paragraphs.

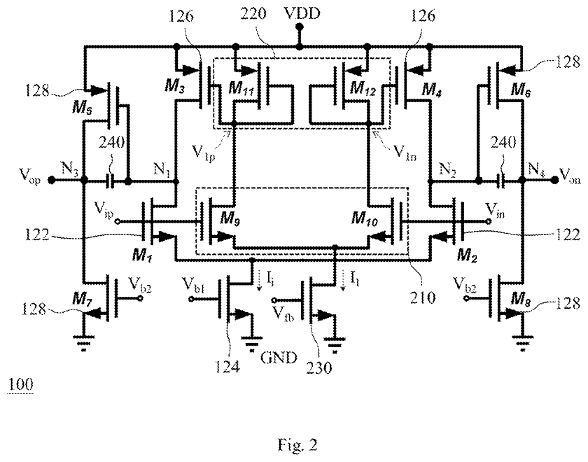

FIG. 2 shows an embodiment of the first amplifying circuit 110 of FIG. 1. The first amplifying circuit 110 of FIG. 2 includes a signal input circuit 210 and a diode-connected circuit 220. A nonrestrictive embodiment of the signal input circuit 210 is a pair of NMOS transistors M₉, M₁₀. The pair of NMOS transistors M₉, M₁₀ is configured to receive the input signal V₁ₚ, V₁ₙ with its gate terminals and output the first amplified signal V₁ₚ, V₁ₙ with its drain terminals. It is noted that the signal input circuit 210 can be realized with a pair of PMOS transistors according to implementation needs. A nonrestrictive embodiment of the diode-connected circuit 220 is a pair of PMOS transistors M₁, M₁₂. The pair of PMOS transistors M₁₁, M₁₂ is coupled between the high-voltage terminal VDD and the signal input circuit 210, and is configured to determine the transconductance of the first amplifying circuit 110 (e.g., Gm_{9,10}/Gm_{11,12} in the equations (1)˜(2)) in conjunction with the signal input circuit 210, which can be appreciated from the equations (1)˜(2) mentioned in the next paragraph. It is noted that: the diode-connected circuit 220 and the aforementioned transconductance and loading circuit 126 jointly function as a current mirror; the common-mode feedback signal (i.e., the feedback voltage Vb mentioned in the next paragraph) is inputted to the below-mentioned bias circuit 230, and used to achieve the efficacy of DC stabilization through the current mirror.

Referring to FIG. 2, the first amplifying circuit 110 further includes a bias circuit 230. A nonrestrictive embodiment of the bias circuit 230 is an NMOS transistor that is coupled between the signal input circuit 210 and the low-voltage terminal GND and configured to regulate the current I1 passing through the signal input circuit 210 according to a feedback voltage V_{fb}. In addition, in order to stabilize the amplifying circuit 100, a capacitor circuit 240 can optionally be set between the set of intermediate node(s) N₁, N₂ and a set of output node(s) N₃, N₄ for outputting the output signal Vₒₚ, Vₒₙ as shown in FIG. 2. Based on the circuit configuration of FIG. 2, the bandwidth F_{T} and the gain Av of the amplifying circuit 100 can be represented by the following equation (1) and equation (2) respectively:

$${F}_{T} = 2 {πω}_{T} , {ω}_{T} = ( {Gm}_{1 , 2} + \frac{{Gm}_{9 , 10}}{{Gm}_{11 , 12}} {Gm}_{3 , 4} ) / {C}_{C} \qquad eq . ( 1 )$$

$$Av = ( {Gm}_{1 , 2} + \frac{{Gm}_{9 , 10}}{{Gm}_{11 , 12}} {Gm}_{3 , 4} ) ( {Ro}_{1 , 2} ‖ {Ro}_{3 , 4} ) \times {Gm}_{5 , 6} ( {Ro}_{5 , 6} ‖ {Ro}_{7 , 8} ) \qquad eq . ( 2 )$$

In the equations (1)˜(2), ω_{T} denotes an angular frequency, Gm_{i,j} denotes the transconductance contributed by the transistors Mᵢ, Mⱼ of FIG. 2 (e.g., Gm_{1,2} contributed by the transistors M₁, M₂), C_{C} denotes the capacitance of the capacitor circuit 240, Ro_{p,q} denotes the output impedance contributed by the transistors Mₚ, M_{q} of FIG. 2 (e.g., Ro_{1,2} contributed by the transistors M₁, M₂).

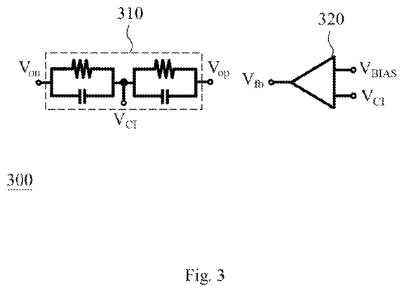

FIG. 3 shows a feedback voltage generating circuit 300 which can be included in the first amplifying circuit 110 or be set outside the first amplifying circuit 110. The feedback voltage generating circuit 300 includes a common-mode reference voltage generating circuit 310 and a comparison circuit 320. The common-mode reference voltage generating circuit 310 includes two sets of resistor-and-capacitor circuits that are connected in series, wherein each of the two sets of resistor-and-capacitor circuits includes a resistor and a capacitor connected in parallel. The two sets of resistor-and-capacitor circuits are configured to generate a common-mode reference voltage V_{CI} according to the aforementioned output signal Vₒₚ, Vₒₙ. The comparison circuit 320 is configured to compare the common-mode reference voltage V_{CI} with a predetermined voltage V_{BIAS} to generate the aforementioned feedback voltage V_{fb}, wherein the predetermined voltage V_{BIAS} is determined according to implementation needs.

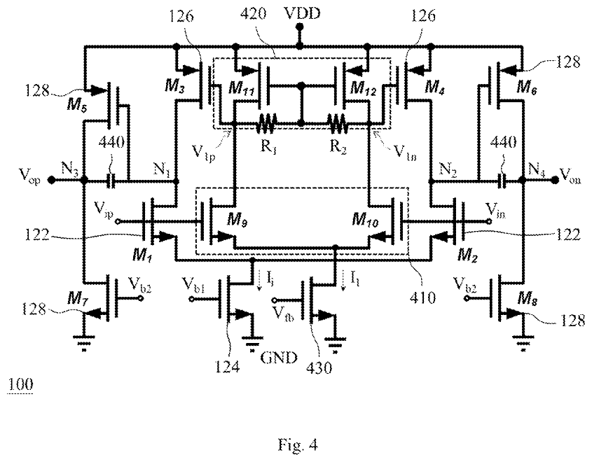

FIG. 4 shows another embodiment of the first amplifying circuit 110 of FIG. 1. The first amplifying circuit 110 of FIG. 4 includes a signal input circuit 410 and a loading circuit 420. A nonrestrictive embodiment of the signal input circuit 410 is a pair of NMOS transistors M₉, M₁₀. The pair of NMOS transistors M₉, M₁₀ is configured to receive the input signal Vᵢₚ, Vin with its gate terminals and output the first amplified signal V₁ₚ, V₁ₙ with its drain terminals. It is noted that the signal input circuit 210 can be realized with a pair of PMOS transistors according to implementation needs. A nonrestrictive embodiment of the loading circuit 420 includes a pair of PMOS transistors M₁₁, M₁₂ and a resistor circuit (e.g., a circuit composed of R₁, R₂ in FIG. 4). The pair of PMOS transistors M₁₁, M₁₂ is coupled between the high-voltage terminal VDD and the signal input circuit 410, and is configured to determine the output impedance of the first amplifying circuit 110 (e.g., (Ro_{9,10}∥Ro_{11,12}) in the equations (3)˜(4)) in conjunction with the signal input circuit 410, which can be appreciated from the equations (3)˜(4) mentioned in the next paragraph. It is noted that: the resistor circuit is coupled between the gate terminals of the pair of PMOS transistors M₁₁, M₁₂ and the drain terminals of the pair of PMOS transistors M₁₁, M₁₂, and is further coupled with the input-stage circuit 122 of the aforementioned second amplifying circuit 120; accordingly, the resistor circuit uses the characteristic of a differential signal to assist the amplifying circuit 100 in achieving a large bandwidth through a smaller current. From a viewpoint based on a DC common-mode analysis, the loading circuit 420 and the transconductance and loading circuit 126 jointly function as a current mirror and achieve the efficacy of common-mode stabilization.

Referring to FIG. 4, the first amplifying circuit 110 further includes a bias circuit 430. The bias circuit 430 is coupled between the signal input circuit 410 and the low-voltage terminal GND, and configured to regulate the current I₁ passing through the signal input circuit 410 according to a feedback voltage V_{fb}, wherein the feedback voltage V_{fb} can be generated by the circuit configuration of FIG. 3. In addition, in order to stabilize the amplifying circuit 100, a capacitor circuit 440 can optionally be set between the set of intermediate node(s) N₁, N₂ and the set of output node(s) N₃, N₄ for outputting the output signal Vₒₚ, Vₒₙ as shown in FIG. 4. Based on the circuit configuration of FIG. 4, the bandwidth F_{T} and the gain Av of the amplifying circuit 100 can be represented by the following equation (3) and equation (4) respectively:

$${F}_{T} = 2 {πω}_{T} , {ω}_{T} = [ {Gm}_{1 , 2} + {Gm}_{9 , 10} ( {Ro}_{9 , 10} ‖ {Ro}_{11 , 12} ) {Gm}_{3 , 4} ] / {C}_{C} \qquad eq . ( 3 )$$

$$Av = [ {Gm}_{1 , 2} + {Gm}_{9 , 10} ( {Ro}_{9 , 10} ‖ {Ro}_{11 , 12} ) {Gm}_{3 , 4} ] \text{} ( {Ro}_{1 , 2} ‖ {Ro}_{3 , 4} ) \times {Gm}_{5 , 6} ( {Ro}_{5 , 6} ‖ {Ro}_{7 , 8} ) \qquad eq . ( 4 )$$

In the equations (3)˜(4), WT denotes an angular frequency, Gm_{i,j} denotes the transconductance contributed by the transistors Mᵢ, Mⱼ of FIG. 4 (e.g., Gm_{1,2} contributed by the transistors M₁, M₂), C_{C} denotes the capacitance of the capacitor circuit 440, Ro_{p,q} denotes the output impedance contributed by the transistors Mₚ, M_{q} of FIG. 4 (e.g., Ro_{9,10} contributed by the transistors M₉, M₁₀).

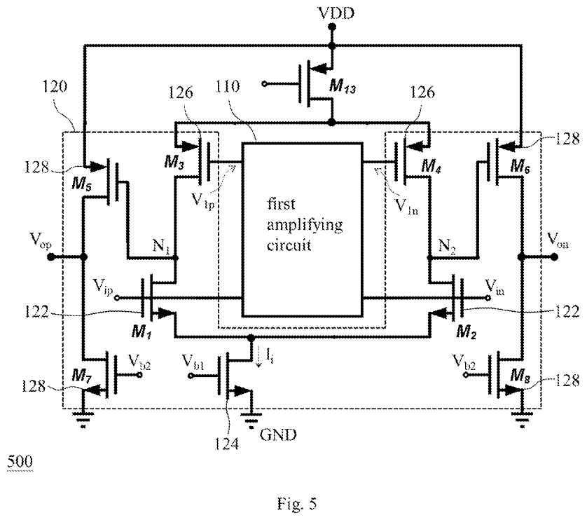

FIG. 5 shows another embodiment of the amplifying circuit of the present disclosure. In comparison with FIG. 1, the amplifying circuit 500 of FIG. 5 further includes a cascode transistor M₁₃ coupled between the high-voltage terminal VDD and the first amplifying circuit 110. Since those having ordinary skill in the art can refer to the disclosure of the embodiments of FIGS. 1˜4 to appreciate the detail and the modification of the embodiment of FIG. 5, repeated and redundant description is omitted here.

It is noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention is flexible based on the present disclosure.

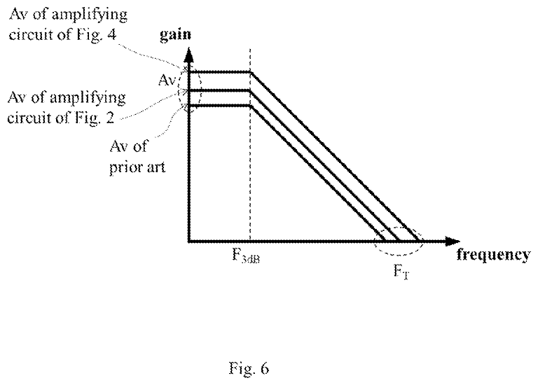

FIG. 6 shows the relation between the gain (Av) and the frequency with respect to the prior art (e.g., the two-stage operational amplifier mentioned in the description of related art of this specification), the amplifying circuit 100 of FIG. 2, and the amplifying circuit 100 of FIG. 4. As shown in FIG. 6, provided the 3 dB frequencies of the prior art, the amplifying circuit 100 of FIG. 2, and the amplifying circuit 100 of FIG. 4 are the same, the gain of the prior art is the smallest one, the gain of the amplifying circuit 100 of FIG. 2 is the medium one, and the gain of the amplifying circuit 100 of FIG. 4 is the largest one. In addition, as shown in FIG. 6, the cutoff frequency F_{T} (or alternatively, the bandwidth) of the prior art is the smallest one, the cutoff frequency F_{T} (or alternatively, the bandwidth) of the amplifying circuit 100 of FIG. 2 is the medium one, and the cutoff frequency F_{T} (or alternatively, the bandwidth) of the amplifying circuit 100 of FIG. 4 is the largest one.

To sum up, the amplifying circuit of the present disclosure allows its loading circuit (i.e., the transconductance and loading circuit 126 composed of transistors M₃, M₄ in FIG. 1) to contribute to the transconductance of the amplifying circuit, and thereby increases the bandwidth of the amplifying circuit.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An amplifying circuit, comprising:
a first amplifying circuit coupled between a high-voltage terminal and a low-voltage terminal and configured to output a first amplified signal according to an input signal; and
a second amplifying circuit including:
an input-stage circuit configured to receive the input signal and accordingly output an input-stage output signal to a set of intermediate node(s);
a transconductance and loading circuit coupled between the high-voltage terminal and the input-stage circuit, and configured to output a transconductance-enhancement signal to the set of intermediate node(s) according to the first amplified signal; and
an output-stage circuit coupled between the high-voltage terminal and the low-voltage terminal and further coupled to the set of intermediate node(s), and configured to output an output signal according to the input-stage output signal and the transconductance-enhancement signal.

2. The amplifying circuit of claim 1, wherein the first amplifying circuit includes:
a signal input circuit including a set of input terminal(s) and a set of output terminal(s), the signal input circuit configured to receive the input signal with the set of input terminal(s) and output the first amplified signal with the set of output terminal(s); and
a diode-connected circuit coupled between the high-voltage terminal and the set of output terminal(s), and configured to determine a transconductance of the first amplifying circuit in conjunction with the signal input circuit.

3. The amplifying circuit of claim 2, wherein the diode-connected circuit and the transconductance and loading circuit of the second amplifying circuit jointly function as a current mirror.

4. The amplifying circuit of claim 2, wherein the signal input circuit is a pair of NMOS transistors, and the set of input terminal(s) and the set of output terminal(s) are gate terminals of the pair of NMOS transistors and drain terminals of the pair of NMOS transistors respectively; and the diode-connected circuit is a pair of PMOS transistors.

5. The amplifying circuit of claim 2, wherein the first amplifying circuit further includes: a bias circuit coupled between the signal input circuit and the low-voltage terminal, and configured to regulate a current from the signal input circuit to the low-voltage terminal.

6. The amplifying circuit of claim 5, wherein the first amplifying circuit further includes:
a common-mode reference voltage generating circuit configured to generate a common-mode reference voltage according to the output signal; and
a comparison circuit configured to compare the common-mode reference voltage with a predetermined voltage to output a feedback voltage to the bias circuit so as to allow the bias circuit to regulate the current according to the feedback voltage.

7. The amplifying circuit of claim 1, wherein the first amplifying circuit includes:
a signal input circuit including a set of input terminal(s) and a set of output terminal(s), the signal input circuit configured to receive the input signal with the set of input terminal(s) and output the first amplified signal with the set of output terminal(s); and
a loading circuit coupled between the high-voltage terminal and the set of output terminal(s), and configured to determine an output impedance of the first amplifying circuit in conjunction with the signal input circuit.

8. The amplifying circuit of claim 7, wherein the loading circuit includes:
a pair of loading transistors coupled between the high-voltage terminal and the set of output terminal(s); and
a resistor circuit coupled between gate terminals of the pair of loading transistors and drain terminals of the pair of loading transistors, and further coupled with the input-stage circuit of the second amplifying circuit.

9. The amplifying circuit of claim 8, wherein the signal input circuit is a pair of NMOS transistors, and the set of input terminal(s) and the set of output terminal(s) are gate terminals of the pair of NMOS transistors and drain terminals of the pair of NMOS transistors respectively; and the pair of loading transistors is a pair of PMOS transistors.

10. The amplifying circuit of claim 7, wherein the first amplifying circuit further includes: a bias circuit coupled between the signal input circuit and the low-voltage terminal, and configured to regulate a current from the signal input circuit to the low-voltage terminal.

11. The amplifying circuit of claim 10, wherein the first amplifying circuit further includes:
a common-mode reference voltage generating circuit configured to generate a common-mode reference voltage according to the output signal; and
a comparison circuit configured to compare the common-mode reference voltage with a predetermined voltage to output a feedback voltage to the bias circuit so as to allow the bias circuit to regulate the current according to the feedback voltage.

12. The amplifying circuit of claim 1, wherein the second amplifying circuit further includes:
a bias circuit coupled between the input-stage circuit and the low-voltage terminal, and configured to regulate a current from the input-stage circuit to the low-voltage terminal.

13. The amplifying circuit of claim 1, further comprising:
a capacitor circuit coupled between the set of intermediate node(s) and a set of output node(s), wherein the set of output node(s) is used for outputting the output signal.

14. The amplifying circuit of claim 1, further comprising: a cascode transistor coupled between the high-voltage terminal and the first amplifying circuit.

15. The amplifying circuit of claim 1, wherein the input signal is an input differential signal composed of complementary input signals, and the output signal is an output differential signal composed of complementary output signals.

16. The amplifying circuit of claim 1, wherein the input-stage circuit, the transconductance and loading circuit, and the output-stage circuit jointly contribute to a transconductance of the second amplifying circuit.
